(19) United States
(12) Patent Application Publication
(10) Pub. No.: US 2023/0176114 A1
(43) Pub. Date: Jun. 8, 2023

(54) ELECTRICALLY CONNECTING ASSEMBLY OF TEST CONNECTORS

(71) Applicant: HSIN LUNG WU, TAOYUAN CITY (TW)

(72) Inventor: HSIN LUNG WU, TAOYUAN CITY (TW)

(21) Appl. No.: 17/880,382

(22) Filed: Aug. 3, 2022

(30) Foreign Application Priority Data
Dec. 8, 2021 (TW) 110145945

(51) Int. Cl. G01R 31/28

(52) U.S. Cl. CPC G01R 31/2889

(57) ABSTRACT

An electrically connecting assembly has a probe card and a conductive rubber sheet. The probe card has multiple probes. Each of the probes has a first contact end and an inclined guiding segment inclined to a same direction. The conductive rubber sheet is mounted on the probe card, is located in a side of the probe card having the inclined guiding segment, and has a rubber sheet body and multiple wires distributed in the rubber sheet body. The first contact end of each of the probes is capable of contacting a group of the wires. The inclined guiding segment of each of the probes is capable of guiding a direction for the group of the wires to be squeezed and deformed. The electrically connecting assembly prevents the probes from directly abutting the test object to reduce the replacement frequency.

### BACKGROUND OF THE INVENTION

### 1. Field of the Invention

The present invention relates to an electrically connecting assembly of test connectors, especially to an electrically connecting assembly applied in a semiconductor inspection system for semiconductor components or wafers, mounted on an IC test load board of the semiconductor inspection system, and operating as an electrical connection medium between a test object such as semiconductor components or wafers and the IC test load board.

### 2. Description of the Prior Arts

The test connectors currently used in inspection systems for semiconductor components or wafers comprise two categories: probe type test connectors and conductive rubber sheet type test connectors.

In the probe type test connectors, a spring probe of a base is used as a medium of signal transmission during test of test objects such as semiconductor components or wafers. The spring probe is a vertically stretchable component that can adapt the slight height difference between the contact points of the integrated circuit of semiconductor components or wafers and provide a short signal transmission path, which makes the probe type test connectors the mainstream of the test connectors.

However, in the probe type test connectors, an amount of spring probes matches an amount of the contact points and the contact distribution of test objects such as semiconductor components or wafers, and the spring probes are mounted in a base of the probe type test connectors. When the service life of the spring probes installed in the test connectors reaches the limit, the spring probes must be replaced one by one, which causes a lot of burden on the maintenance cost and labor cost of the semiconductor test house. In particular, the input and output contact points of the integrated circuits for test objects such as wafers or semiconductor components are gradually miniaturized and the amount of such is gradually increased. Correspondingly, the amount of the spring probes used in each test connector becomes extremely large and the diameter of such becomes extremely small, such that the replacement of spring probes and the preparation of spare parts cause technical barriers to the development of semiconductor test factories in improving efficiency and reducing costs. Therefore, how to reduce the replacement frequency of the spring probe is a technical problem that needs to be overcome urgently by the semiconductor testing house.

In the conductive rubber sheet type test connectors, a conductive rubber sheet with wires is used as a medium of signal transmission during test of test objects such as semiconductor components or wafers.

However, the conductive rubber sheet with wires is less used in testing larger test connectors in mass production, and the reasons are as follows. When two ends of wire groups inside the conductive rubber sheet are respectively connected to the contact points of the semiconductor components or the wafers and the contact pad of the IC test load board, due to the restriction of the resilience of the conductive rubber sheet, the working stroke of the conductive rubber sheet is extremely short during electrical connection, such that the conductive rubber sheet cannot adapt the slight difference between the contact points of the integrated circuit for larger semiconductor components or wafers. If the working stroke is increased, the force pressing down the tested IC needs to be greatly increased, but this will cause greater deformation of the IC and IC test load board, and the height difference between contact points will become larger, which results in a substantial loss of test accuracy. Additionally, when the wire groups of the conductive rubber sheet are connected to the contact pads of the IC test load board, in each depression and separation during the test of the integrated circuit, each wire group is squeezed up and down, thereby fractioning the contact pad, which gradually damages the IC test load board contact pad, and that is another major reason for the massive loss of accuracy in mass production tests.

To overcome the shortcomings, the present invention provides an electrically connecting assembly to mitigate or obviate the aforementioned problems.

### SUMMARY OF THE INVENTION

The main objective of the present invention is to provide an electrically connecting assembly that solves the time-consuming and labor-intensive problem of the conventional test connectors caused by the frequent replacement of the spring probes. The electrically connecting assembly of the present invention also solves the problem that the working stroke is too short and the contact pads of the IC test load board are easily damaged when the wire groups of the conductive rubber sheet of the conventional test connectors contact the test object such as IC test load board, causing semiconductor test factories to avoid adopting larger semiconductor components or wafers in mass production testing.

The electrically connecting assembly has a probe card and a conductive rubber sheet. The probe card has an insulation board and multiple probes. The probes are mounted in the insulation board. Each of the probes has a first contact end, a second contact end, and an inclined guiding segment. The inclined guiding segment is formed on the first contact end. The inclined guiding segments of the probes are inclined to a same direction. The conductive rubber sheet is mounted on the probe card, is located in a side of the probe card having the inclined guiding segment, and has a rubber sheet body and multiple wires. The wires are distributed in the rubber sheet body. The first contact end of each of the probes is capable of contacting a group of the wires. The inclined guiding segment of each of the probes is capable of guiding a direction for the group of the wires to be squeezed and deformed.

The electrically connecting assembly can be mounted on an IC test load board of a semiconductor inspection system for semiconductor components or wafers and operates as an electrical connection medium between a test object such as semiconductor components or wafers and the IC test load board. The electrically connecting assembly has the following advantages:

1. The electrically connecting assembly is a combination of a probe card and a conductive rubber sheet. By the flexibility and the resilience of the conductive rubber sheet, the electrically connecting assembly is capable of adapting the slight height difference between the contact points of the test objects such as semiconductor components or wafers and the contact points of the integrated circuit, so that every contact point of the test objects can be electrically connected to the contact pad corresponding in position of the inspection system via the electrically connecting assembly.

2. By the probe card having the inclined guiding segment formed on the first contact end, and the conductive rubber sheet mounted on the side of the probe card having the inclined guiding segment, the wires of the conductive rubber sheet can contact the contact end corresponding in position of the probe, and the inclined guiding segment guides a direction for the wire group to be squeezed and deformed, so the wire group is restricted to be squeezed and deformed toward a same direction. Therefore, the contact points of the test objects such as semiconductor components or wafers are correctly electrically connected to the contact end corresponding in position of the probe via the wire group of the conductive rubber sheet, thereby effectively preventing wrong contact of the wire group.

3. The electrically connecting assembly is a combination of a probe card and a conductive rubber sheet. By the flexibility and the resilience of the conductive rubber sheet, and the guiding function of the inclined guiding segment applied on the wire group that guides the squeezed and deformed direction for the wires, the surface oxide layer of each contact point of test objects such as semiconductor components or wafers is penetrated by multiple wires of one wire group, and said wires contact the main body of the contact point inside to form an optimal electrical connection.

Besides, by the inclined guiding segment of the probe being a recess and guiding a direction for the wires to be squeezed and deformed, the wire group can match the shape of a ball-shaped contact point after squeezed and deformed to expand the contact area between the wire group and the ball-shaped contact point and to form more electrical contact points, thereby enhancing testability for the test objects such as semiconductor components or wafers.

The electrically connecting assembly contact the test objects such as semiconductor components or wafers by the conductive rubber sheet to prevent the probes from directly abutting the contact points of the test objects to substantially reduce the replacement frequency due to friction of the spring probes. The surface of the conductive rubber sheet is easy to clean, thus ensuring correct inspection operations. Further, the conductive rubber sheet can be replaced integrally, which makes the replacing process simple and less time-consuming, thereby improving efficiency and reducing cost for the semiconductor test house.

In addition, the probes of the probe card can be spring probes. By the axial stretchability and elasticity of the spring probe and the resilience of the conductive rubber sheet, the electrically connecting assembly can adapt the height difference between the contact points of larger integrated circuits such as larger semiconductor components or wafers.

Other objectives, advantages and novel features of the invention will become more apparent from the following detailed description when taken in conjunction with the accompanying drawings.

### BRIEF DESCRIPTION OF THE DRAWINGS

FIG. 1 is a side view in cross-section of a first embodiment of an electrically connecting assembly in accordance with the present invention;

FIG. 2 is an operational side view in cross-section of the first embodiment of the electrically connecting assembly in FIG. 1, showing the electrically connecting assembly used in a semiconductor component test;

FIG. 3 is partially enlarged view of FIG. 2;

FIG. 4 is a side view in cross-section of a second embodiment of an electrically connecting assembly in accordance with the present invention;

FIG. 5 is an operational side view in cross-section of the second embodiment of the electrically connecting assembly in FIG. 4, showing the electrically connecting assembly used in a semiconductor component test;

FIG. 6 is a side view in cross-section of a third embodiment of an electrically connecting assembly in accordance with the present invention;

FIG. 7 is an operational side view in cross-section of the third embodiment of the electrically connecting assembly in FIG. 6, showing the electrically connecting assembly used in a semiconductor component test;

FIG. 8 is a side view in cross-section of a fourth embodiment of an electrically connecting assembly in accordance with the present invention;

FIG. 9 is a side view in cross-section of a fifth embodiment of an electrically connecting assembly in accordance with the present invention;

FIG. 10 is an operational side view in cross-section of the fifth embodiment of the electrically connecting assembly in FIG. 9, showing the electrically connecting assembly used in a semiconductor component test;

FIG. 11 is another operational side view in cross-section of the first embodiment of the electrically connecting assembly in FIG. 1, showing the electrically connecting assembly used in a wafer test; and

FIG. 12 is another operational side view in cross-section of the fifth embodiment of the electrically connecting assembly in FIG. 9, showing the electrically connecting assembly used in a wafer test.

### DETAILED DESCRIPTION OF THE PREFERRED EMBODIMENTS

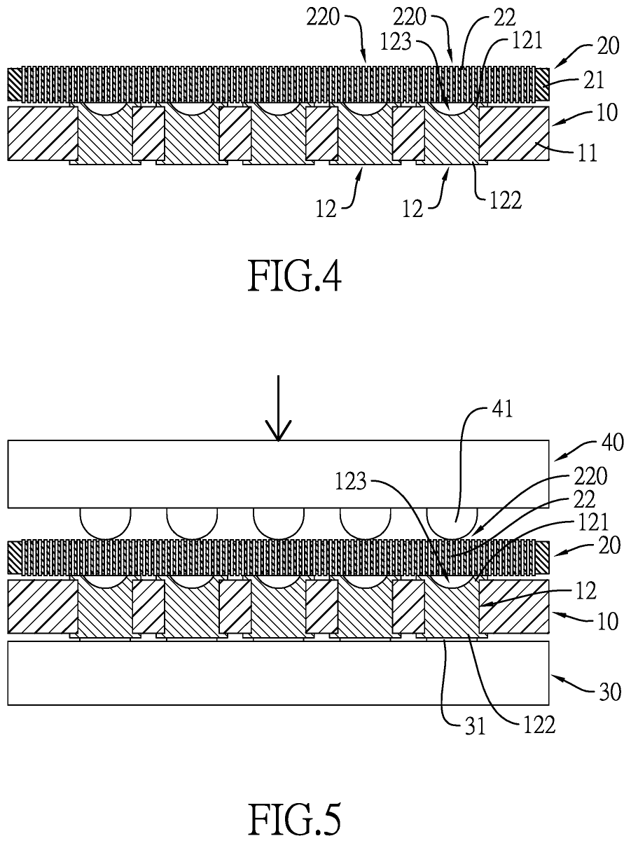

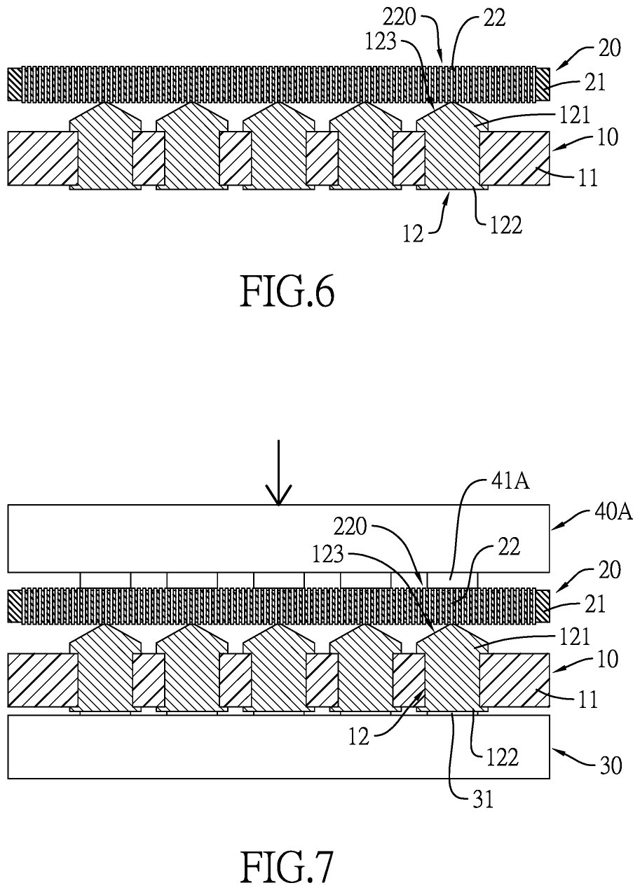

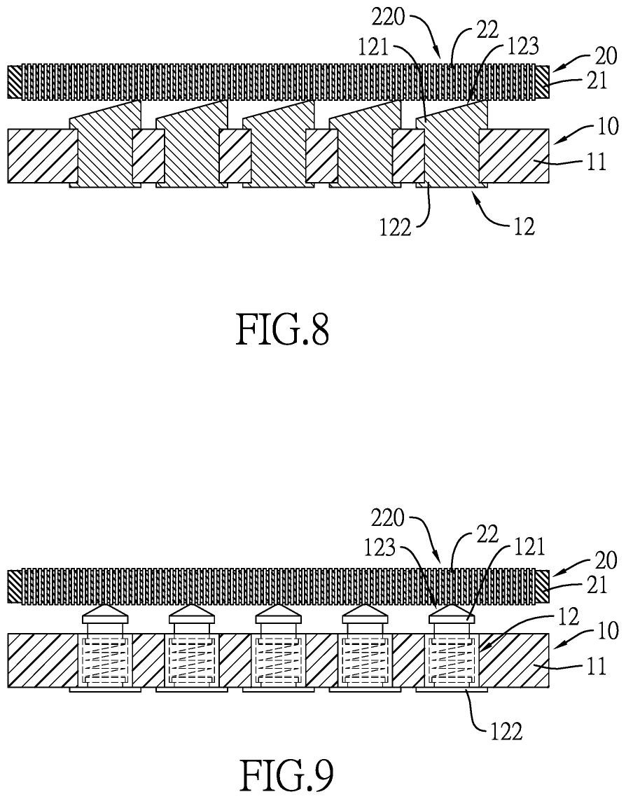

With reference to FIGS. 1, 4, 6, 8, and 9, multiple embodiments are shown in these drawings. An electrically connecting assembly in accordance with the present invention comprises a probe card 10 and a conductive rubber sheet 20.

With reference to FIGS. 1, 4, 6, 7, 8, and 9, the probe card 10 has an insulation board 11 and multiple probes 12 mounted in the insulation board 11. An amount of the probes 12 matches an amount of contact pads 31 of an IC test load board 30 or matches an amount of contact points 41, 41A of a semiconductor component 40, 40A. The probes 12 correspond in positions to the contact pads 31 of the IC test load board 30 or correspond in positions to the contact points 41, 41A of a semiconductor component 40, 40A. With reference to FIGS. 1, 4, 6, 7, and 8, each of the probes 12 is a spring probe or each of the probes has a fixed length.

With reference to FIGS. 1, 4, 6, 8, and 9, each of the probes 12 has a first contact end 121 and a second contact end 122. The first contact end 121 and the second contact end 122 are respectively exposed from two sides of the insulation board 11. An inclined guiding segment 123 is formed on the first contact end 121 of each of the probes 12. The inclined guiding segments 123 of the probes 12 are inclined to a same direction. The second contact end 122 can be a flat surface or a protruding arced surface.

With reference to FIGS. 1, 4, 6, 8, and 9, in these preferred embodiments, the inclined guiding segment 123 has a curved or flat sloped surface protruding outward or concave inward, or the inclined guiding segment 123 has an arced surface protruding outward or concave inward (such as a semispherical surface).

With reference to FIGS. 1, 4, 6, and 8, in these preferred embodiments, the inclined guiding segment 123 can be a recess in a conical shape, in a semispherical shape, with double flat slopes, or with one single flat slope. Alternatively, the inclined guiding segment 123 can be a protrusion in a conical shape, in a semispherical shape, with double flat slopes, or with one single flat slope. With reference to FIGS. 1, 4, 6, 8, and 9, the conductive rubber sheet 20 is mounted on the probe card 10 and is located in a side of the probe card 10 having the inclined guiding segment 123. The conductive rubber sheet 20 has a rubber sheet body 21 and multiple wires 22. The rubber sheet body 21 is made of elastic materials such as rubber. The wires 22 are distributed in the rubber sheet body 21. Each of the wires 22 extends from a side of the rubber sheet body 21 to another side of the rubber sheet body 21. Two ends of each of the wires 22 respectively protrude from two side surfaces of the rubber sheet body 21. An area of the wires 22 distributed in the rubber sheet body 21 allows each of the probes 12 of the probe card 10 to be electrically connected to a group of the wires 22 corresponding in position (hereinafter referred to as wire group 220). The inclined guiding segment 123 guides a direction for the wire group 220 to be squeezed and deformed, so wires of the wire group 220 are restricted to be squeezed and deformed toward a same direction.

The way that the wires 22 of the conductive rubber sheet 20 are distributed in the rubber sheet body 21 can be determined according to needs. The wires 22 can be distributed in the rubber sheet body 21 vertically, substantially vertically, or inclinedly. In this preferred embodiment, an angle between the wires 22 and a side surface of the rubber sheet body 21 is 60 degrees to 90 degrees. When the angle between the wires 22 and the side surface of the rubber sheet body 21 is 90 degrees, the wires 22 are distributed in the rubber sheet body 21 vertically. When using a thin conductive rubber sheet 20, the wires 22 are preferably distributed in the rubber sheet body 21 inclinedly, so that the wires 22 and the rubber sheet body 21 are assembled well to prevent separation. Besides, the wire 22 is short so a lateral distance between an upper end and a lower end of the wire 22 is short. On the contrary, when using a thick conductive rubber sheet 20, the wires 22 are preferably distributed in the rubber sheet body 21 vertically or substantially vertically.

The applicable test object of the electrically connecting assembly tests can be, but is not limited to, a ball-grid-array semiconductor component (BAG), a land-grid-array semiconductor component (LGA), or quad flat no-lead package semiconductor component (QFN). In order to facilitate instruction, the followings are taking testing operations of the electrically connecting assembly applied to BGA and LGA type semiconductor components for example, and the testing operations of other types of semiconductor components are analogous and will not be repeated.

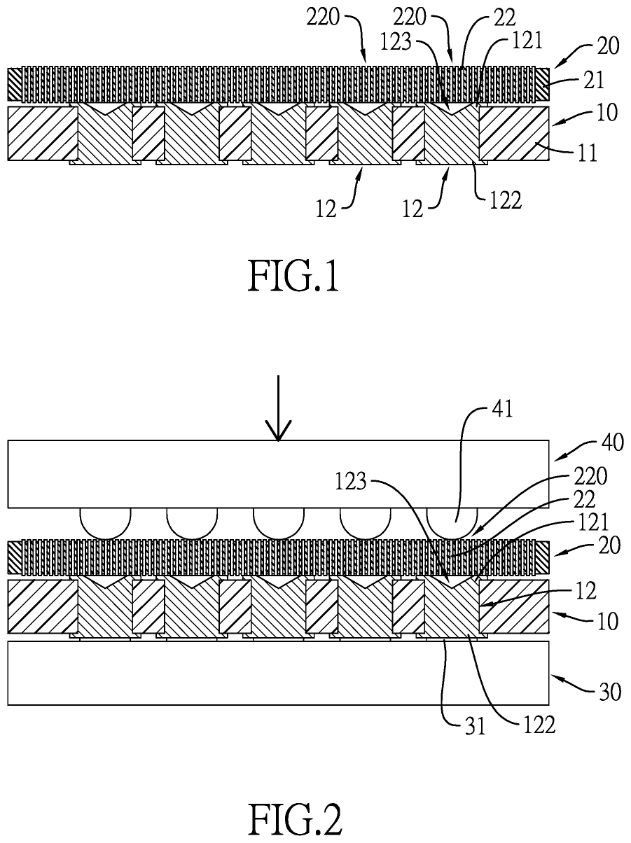

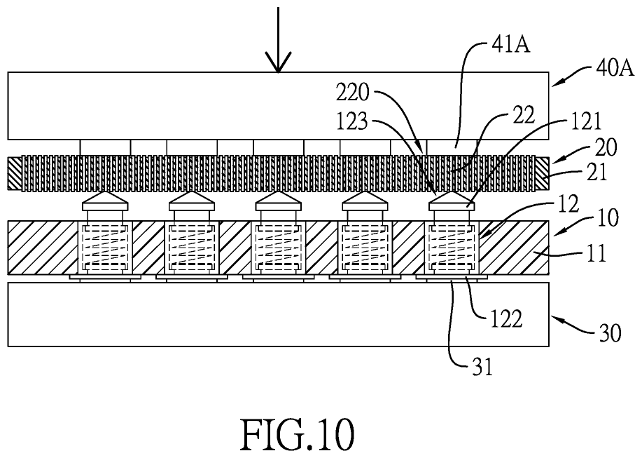

With reference to FIGS. 2, 3, 5, 7, and 10, the conductive rubber sheet 20 is mounted on the probe card 10. The electrically connecting assembly is mounted on the IC test load board 30 of the semiconductor component 40, 40A via a base, which is not shown in the drawings and is a well-known component in the test connectors. The probe card 10 is placed on the IC test load board 30. The second contact ends 122 of the probes 12 are electrically connected to the contact pads 31 of the IC test load board 30 corresponding in positions. The conductive rubber sheet 20 mounted on the probe card 10 is used as an electrically connecting medium for the semiconductor component 40, 40A.

When testing the semiconductor component 40, 40A, the semiconductor component 40, 40A is placed on the conductive rubber sheet 20 and is pressed downward. The contact points 41, 41A of the semiconductor component 40, 40A abut and press the conductive rubber sheet 20. By the flexibility and resilience of the conductive rubber sheet 20, each of the contact points 41, 41A of the semiconductor component 40, 40A is allowed to contact one of the wire groups 220 corresponding in position via the conductive rubber sheet 20, so as to eliminate the height difference between the contact points 41, 41A of the semiconductor component 40, 40A. Each of the wire groups 220 contacts the corresponding inclined guiding segment 123, and the inclined guiding segment 123 guides a direction for the wire group 220 to be squeezed and deformed, so the wire group 220 is restricted to be squeezed and deformed toward a same direction, and thus the contact points 41, 41A of the semiconductor component 40, 40A are electrically connected to the corresponding probes 12 via the wire groups 220 correctly. The probes 12 of the probe card 10 are respectively electrically connected to the contact pads 31 of the IC test load board 30 corresponding in positions, and the inspection system tests the semiconductor components 40, 40A via the IC test load board 30 and the electrically connecting assembly.

In the abovementioned testing process of the semiconductor components 40, 40A, the electrically connecting assembly in the present invention uses the combination of the probe card 10 and the conductive rubber sheet 20, and uses the flexibility and resilience of the conductive rubber sheet 20 to eliminate the slight height difference between the contact points 41, 41A of the semiconductor component 40, 40A, and therefore each of the contact points 41, 41A of the semiconductor component 40, 40A can be electrically connected to the contact pads 31 of the IC test load board 30 corresponding in positions via the electrically connecting assembly of the present invention.

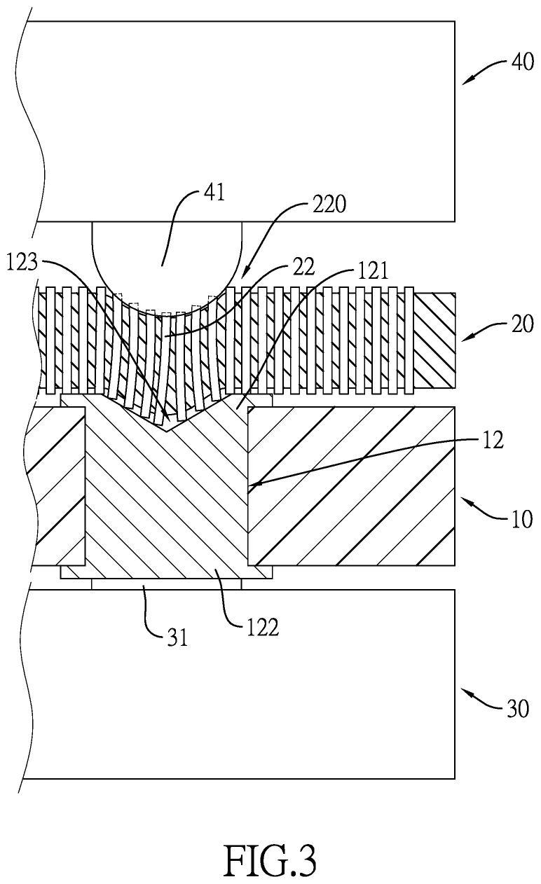

On the other hand, the electrically connecting assembly in the present invention uses the inclined guiding segment 123 of the probes 12 to guide the direction for the wire groups 220 to be squeezed and deformed, so the wire groups 220 are restricted to be squeezed and deformed toward a same direction, and thus the surface oxide layer of each of the contact points 41, 41A of the semiconductor component 40, 40A can be penetrated by multiple wires 22 of one of the wire groups 220, and said wires 22 contact the main body of the contact point 41, 41A inside to form an optimal electrical connection. Especially with reference to FIG. 3, since the inclined guiding segment 123 of the probe 12 is a recess, the guiding function of the inclined guiding segment 123 makes the wire group 220 squeezed and deformed to attach to and match a ball-shaped contact point 41. In such case, a contact area between the wire group 220 and the ball-shaped contact point 41 can be expanded, thereby increasing the testing performance of the test to the semiconductor components 40.

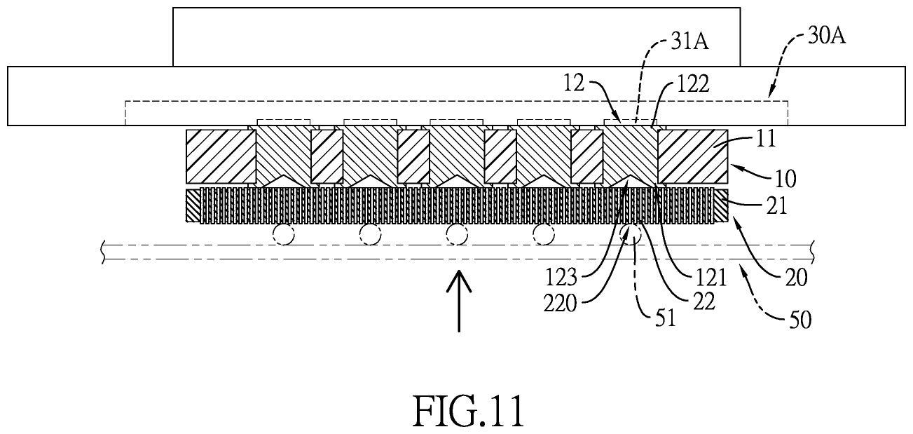

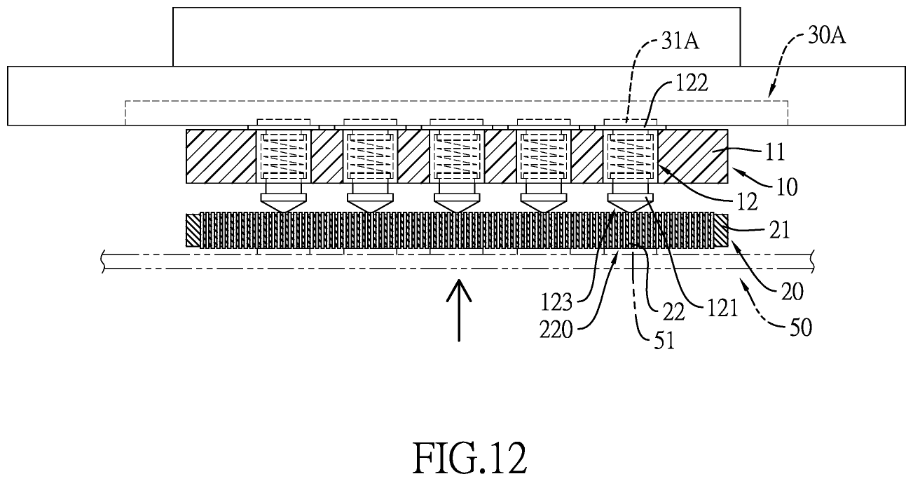

With reference to FIGS. 11 and 12, the drawings show preferred embodiments of the electrically connecting assembly of test connectors applied to a wafer testing process, which indicates that the electrically connecting assembly can be applied to both semiconductor components or wafers testing process, and is not limited thereto.

With reference to FIGS. 11 and 12, the electrically connecting assembly of test connectors in the present invention is invertedly installed in a wafer inspection system. The probe card 10 or the conductive rubber sheet 20 is mounted on a bottom surface of the IC test load board 30A. The contact pads 31A of the IC test load board 30A are respectively electrically connected to the probes 12 of the probe card 10 corresponding in positions, or are respectively electrically connected to the wire groups 220 of the conductive rubber sheet 20 corresponding in positions. The probe card 10 under the conductive rubber sheet 20 or the conductive rubber sheet 20 under the probe card 10 is used as an electrically connecting medium during testing. When the wafer 50 is pushed upward, the way of each of the contact points 51 of the wafer 50 electrically connected to the contact points 31A of the IC test load board 30A is identical to the way of the testing to semiconductor components.

According to the above, the electrically connecting assembly of test connectors of the present invention uses the combination of the probe card 10 and the conductive rubber sheet 20. By the flexibility and resilience of the conductive rubber sheet 20, the slight height difference between the contact points 41, 41A, 51 of the semiconductor components 40, 40A and the wafers 50 can be eliminated, so that the contact points 41, 41A, 51 of the semiconductor components 40, 40A and the wafers 50 can all be electrically connected to the contact pads 31 of the IC test load board 30 correctly. Moreover, the inclined guiding segments 123 of the probes 12 of the probe card 10 are inclined to a same direction, and the conductive rubber sheet 20 is mounted on the side of the probe card 10 having the inclined guiding segments 123, so the wires 22 of the conductive rubber sheet 20 can contact the inclined guiding segments 123 corresponding in positions and can be guided to be squeezed and deformed toward a same direction. Thus, the electrically connecting assembly offers correct and stable connections and signal paths to ensure the correctness of test of the semiconductor components 40, 40A or the wafers 50.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. An electrically connecting assembly comprising:
a probe card having
an insulation board;
multiple probes mounted in the insulation board; each of the probes having
a first contact end;
a second contact end;
an inclined guiding segment formed on the first contact end; the inclined guiding segments of the probes inclined to a same direction;
a conductive rubber sheet mounted on the probe card, located in a side of the probe card having the inclined guiding segment, and having
a rubber sheet body;
multiple wires distributed in the rubber sheet body; the first contact end of each of the probes being capable of contacting a group of the wires; the inclined guiding segment of each of the probes being capable of guiding a direction for the group of the wires to be squeezed and deformed.

2. The electrically connecting assembly as claimed in claim 1, wherein the inclined guiding segment has a curved slope surface protruding outward or concave inward, or the inclined guiding segment has an arced surface protruding outward or concave inward.

3. The electrically connecting assembly as claimed in claim 1, wherein the inclined guiding segment has an inclined surface protruding outward or concave inward.

4. The electrically connecting assembly as claimed in claim 1, wherein
each of the wires extends from a side of the rubber sheet body to another side of the rubber sheet body;
two ends of each of the wires respectively protrude from two side surfaces of the rubber sheet body; and
each of the probes is a spring probe or each of the probes has a fixed length.

5. The electrically connecting assembly as claimed in claim 2, wherein
each of the wires extends from a side of the rubber sheet body to another side of the rubber sheet body;
two ends of each of the wires respectively protrude from two side surfaces of the rubber sheet body; and
each of the probes is a spring probe or each of the probes has a fixed length.

6. The electrically connecting assembly as claimed in claim 3, wherein
each of the wires extends from a side of the rubber sheet body to another side of the rubber sheet body;
two ends of each of the wires respectively protrude from two side surfaces of the rubber sheet body; and
each of the probes is a spring probe or each of the probes has a fixed length.
